(19) United States
(12) Patent Application Publication
(10) Pub. No.: US 2011/0226304 A1
(43) Pub. Date: Sep. 22, 2011

(54) Thermoelectric Conversion Module

(75) Inventors: Sachiko Hayashi, Kyoto-Fu (JP); Takanori Nakamura, Nagaokakyo-shi (JP)

(73) Assignee: MURATA MANUFACTURING CO., LTD.

(21) Appl. No.: 13/109,259

(22) Filed: May 17, 2011

Related U.S. Application Data
(63) Continuation of application No. PCT/JP2008/071100, filed on Nov. 20, 2008.

(51) Int. Cl. H01L 35/04; H01L 35/22

(52) U.S. Cl. 136/238

(57) ABSTRACT

A thermoelectric conversion module that generates electric power by applying a temperature difference to a pn junction between a p-type oxide thermoelectric conversion material and an n-type oxide thermoelectric conversion material, at least one surface of a pair of surfaces to which a temperature difference is to be applied is covered with an insulating film. Surfaces other than the surfaces to which the temperature difference is to be applied are also covered with an insulating film. The p-type oxide thermoelectric conversion material, the n-type oxide thermoelectric conversion material, an insulating material arranged therebetween, and the insulating film that covers a predetermined region of the surface are co-sintered.

### CROSS REFERENCE TO RELATED APPLICATIONS

The present application is a continuation of International Application No. PCT/JP2008/071100, filed Nov. 20, 2008, the entire contents of which is incorporated herein by reference in its entirety.

### FIELD OF THE INVENTION

The present invention relates to a thermoelectric conversion module, and more specifically, to a technique for improving the thermoelectric conversion efficiency of a thermoelectric conversion module containing a p-type oxide thermoelectric conversion material and an n-type oxide thermoelectric conversion material.

### BACKGROUND OF THE INVENTION

To prevent global warming, the reduction of carbon dioxide is a critical issue. Thermoelectric conversion elements capable of directly converting heat into electricity have recently been receiving attention as one effective technique of utilizing waste heat.

For example, as shown in FIG. 8, a thermoelectric conversion element 50 having a structure including a p-type thermoelectric conversion material 51, an n-type thermoelectric conversion material 52, lower-temperature-side electrodes 56, and a higher-temperature-side electrode 58 is known as a conventional thermoelectric conversion element (see Patent Document 1 and FIG. 8).

In the thermoelectric conversion element 50, two types of thermoelectric conversion materials 51 and 52 are provided for energy conversion between heat and electricity and are connected to the lower-temperature-side electrodes 56 at lower-temperature-side junctions 53b, which are defined by end surfaces on a lower-temperature side. Furthermore, the thermoelectric conversion materials 51 and 52 are connected to each other at higher-temperature-side junctions 53a, which are end surfaces on a higher-temperature side, with the higher-temperature-side electrode 58.

In the thermoelectric conversion element 50, the application of a temperature difference between the higher-temperature-side junctions 53a and the lower-temperature-side junctions 53b generates an electromotive force caused by the Seebeck effect, thereby providing electric power.

However, for the structure of the thermoelectric conversion element 50, the electrodes 56 and 58 are used to connect the two thermoelectric conversion materials 51 and 52, thereby disadvantageously producing contact resistance between the electrodes and the thermoelectric conversion materials.

The electric-generating capacity of a thermoelectric conversion element is determined by thermoelectric conversion characteristics of a material and a temperature difference applied to the element, and is also significantly affected by the occupancy of the thermoelectric conversion materials, that is, by the proportion of the area of the thermoelectric conversion materials in a plane perpendicular to the direction of the temperature difference applied to the thermoelectric conversion element. A higher occupancy of the thermoelectric conversion materials leads to an increase in the electric-generating capacity of the thermoelectric conversion element per unit area.

However, in an exemplary conventional structure, such as the thermoelectric conversion element 50, a gap insulation layer is provided between the two thermoelectric conversion materials 51 and 52. Thus, the extent to which the occupancy of the thermoelectric conversion materials can be increased is limited.

Furthermore, since the insulation gap is provided between the two thermoelectric conversion materials 51 and 52, the element is susceptible to damage due to impact by, for example, dropping. Thus, the element disadvantageously has low reliability.
[Patent Document 1] Japanese Unexamined Patent Application Publication No. 11-121815

### SUMMARY OF THE INVENTION

The present invention was accomplished in consideration of the foregoing situation and aims to provide a thermoelectric conversion module which has a high occupancy of thermoelectric conversion materials, which is capable of being directly attached to a heat source made of a conductive material, such as a metal, having excellent heat transfer properties, which has excellent thermoelectric conversion efficiency, and to which a temperature difference is easily applied.

To overcome the foregoing problems, a thermoelectric conversion module of the present invention includes

a p-type oxide thermoelectric conversion material; an n-type oxide thermoelectric conversion material; and a pair of lead-out electrodes, in which the p-type oxide thermoelectric conversion material is directly bonded to the n-type oxide thermoelectric conversion material in one region of a junction surface between the p-type oxide thermoelectric conversion material and the n-type oxide thermoelectric conversion material, the p-type oxide thermoelectric conversion material is bonded to the n-type oxide thermoelectric conversion material with an insulating material provided therebetween in another region of the junction surface to form a pn junction, and

the pair of lead-out electrodes is arranged to output electric power that is generated by applying a temperature difference to the pn junction, and

in which a region of at least one surface of a pair of surfaces at which the p-type oxide thermoelectric conversion material and the n-type oxide thermoelectric conversion material are exposed and to which the temperature difference is to be applied is covered with an insulating film.

In the thermoelectric conversion module of the present invention, a region of each of the pair of surfaces at which the p-type oxide thermoelectric conversion material and the n-type oxide thermoelectric conversion material are exposed and to which the temperature difference is to be applied is preferably covered with an insulating film.

A region of a surface other than the surfaces at which the p-type oxide thermoelectric conversion material and the n-type oxide thermoelectric conversion material are exposed and to which the temperature difference is to be applied is preferably covered with an insulating film.

Preferably, the thermoelectric conversion module is in the form of a rectangular parallelepiped, and each of the pair of lead-out electrodes extends from a corresponding one of a pair of side surfaces to the bottom surface in the vicinity of a ridge serving as a boundary between the bottom surface and the corresponding side surface, the pair of side surfaces being adjacent to the bottom surface, and the bottom surface facing a component on which the thermoelectric conversion module is mounted.

The p-type oxide thermoelectric conversion material, the n-type oxide thermoelectric conversion material, and the insulating material are preferably co-sintered. The insulating film is also preferably co-sintered.

Preferably, the p-type oxide thermoelectric conversion material is primarily made of a substance having a layered perovskite structure represented by the formula: A₂BO₄ (wherein A includes at least La, and B represents at least one element including at least Cu), and the n-type oxide thermoelectric conversion material is primarily made of a substance having a layered perovskite structure represented by the formula: D₂EO₄ (wherein D includes at least one of Pr, Nd, Sm, and Gd, and E represents at least one element including at least Cu).

The insulating material arranged between the p-type oxide thermoelectric conversion material and the n-type oxide thermoelectric conversion material preferably contains an oxide and a glass.

A material constituting the insulating film preferably contains an oxide and a glass.

Advantages

In the thermoelectric conversion module of the present invention, the thermoelectric conversion module having a structure in which the p-type oxide thermoelectric conversion material is directly bonded to the n-type oxide thermoelectric conversion material, the region of at least one surface of the pair of surfaces at which the p-type oxide thermoelectric conversion material and the n-type oxide thermoelectric conversion material are exposed and to which the temperature difference is to be applied is covered with the insulating film. So, even if the thermoelectric conversion module is directly attached to a heat source made of a conductive material, such as a metal, having excellent heat transfer properties, it is possible to provide the thermoelectric conversion module being capable of effectively using heat from the heat source and having excellent thermoelectric conversion efficiency without causing a short-circuit between the p-type oxide thermoelectric conversion material and the n-type oxide thermoelectric conversion material.

In the thermoelectric conversion module of the present invention, the p-type oxide thermoelectric conversion material is directly bonded to the n-type oxide thermoelectric conversion material in one region of the junction surface between the p-type oxide thermoelectric conversion material and the n-type oxide thermoelectric conversion material, and the p-type oxide thermoelectric conversion material is bonded to the n-type oxide thermoelectric conversion material with an insulating material provided therebetween in another region of the junction surface. This results in an increase in the occupancy of the thermoelectric conversion materials, an increase in electric-generating capacity per unit area, and a reduction in resistance at a junction portion as compared to the conventional case in which a p-type oxide thermoelectric conversion material and an n-type oxide thermoelectric conversion material are separated from each other and are connected to each other with an electrode.

Furthermore, the p-type oxide thermoelectric conversion material and the n-type oxide thermoelectric conversion material are bonded directly or with the insulating material provided therebetween, so that they are securely bonded at the junction surface, which improves the impact resistance. Moreover, the thickness of the insulating layer can be reduced as compared to a conventional thermoelectric conversion element having an insulation gap, thereby achieving greater packaging density.

In the present invention, various materials having practical insulation performance and heat resistance may be used as a material for the insulating film. The material for the insulating film preferably has a high thermal conductivity in order to efficiently transfer thermal energy from a heat source.

Examples of an inorganic material suitably used for the insulating film include materials having high thermal conductivities, e.g., Al₂O₃, AlN, and MgO. Usually, a material that contains such a material, a glass, and so forth and that is suitable for film formation is used.

Furthermore, as a material for the insulating film, organic materials, such as acrylic resins and epoxy resins, may be used.

As the insulating material arranged between the p-type oxide thermoelectric conversion material and the n-type oxide thermoelectric conversion material, a material having a low thermal conductivity is preferably used from the viewpoint of ensuring a temperature difference between the pair of surfaces to which the temperature difference is to be applied.

Note that a material the same as the insulating material arranged between the p-type oxide thermoelectric conversion material and the n-type oxide thermoelectric conversion material may be used as a material for the insulating film as long as a thin film made of the material ensures heat transfer properties required.

In a preferred configuration, a region of each of the pair of surfaces at which the p-type oxide thermoelectric conversion material and the n-type oxide thermoelectric conversion material are exposed and to which the temperature difference is to be applied is covered with an insulating film. In this case, it is possible to arrange the thermoelectric conversion module such that each of the pair of surfaces to which the temperature difference is applied is in direct contact with a heat source. This makes it possible to more effectively use heat from the heat source to provide the thermoelectric conversion module having higher thermoelectric conversion efficiency.

In another preferred configuration, the region of a surface other than the surfaces at which the p-type oxide thermoelectric conversion material and the n-type oxide thermoelectric conversion material are exposed and to which the temperature difference is to be applied is covered with the insulating film. In this case, for example, when a plurality of thermoelectric conversion modules are arranged to provide a thermoelectric conversion apparatus, the plural thermoelectric conversion modules each including the insulating films arranged on side surfaces thereof can be arranged so as to be in contact with each other with the insulating films. This results in an increase in the packaging density of the thermoelectric conversion modules, thus improving the electric-generating capacity. In this case, as a material for the insulating films that cover the side surfaces, a low-thermal-conductivity material, such as a substance, e.g., a glass, or a substance containing a low-thermal-conductivity inorganic oxide and a glass, is preferably used from the viewpoint of ensuring a temperature difference between two surfaces to which the temperature difference is to be applied. Note that the material the same as the insulating material arranged between the p-type oxide thermoelectric conversion material and the n-type oxide thermoelectric conversion material may also be used.

In a further configuration, the thermoelectric conversion module is in the form of a rectangular parallelepiped, and each of the pair of lead-out electrodes extends from a corresponding one of a pair of side surfaces to the bottom surface in the vicinity of a ridge serving as a boundary between the bottom surface and the corresponding side surface, the pair of side surfaces being adjacent to the bottom surface, and the bottom surface facing a component on which the thermoelectric conversion module is mounted. This results in improvement in the reliability of the electrical connection between the lead-out electrodes and the outside and improvement in the reliability of the mounting of the thermoelectric conversion module. Furthermore, the area of the electrode on each of the side surfaces can be reduced to some extent without reducing the connection reliability. This results in an increase in the temperature difference between the pair of surfaces to which the temperature difference is to be applied, thereby improving the output.

The p-type oxide thermoelectric conversion material, the n-type oxide thermoelectric conversion material, and the insulating material are preferably co-sintered to provide a co-sintered structure. This is preferred because it leads to the simplification of the production process, an increase in the reliability of the junction of the materials, and resulting improvement in characteristics.

The insulating film may also be co-sintered. This makes the present invention more effective.

The p-type oxide thermoelectric conversion material is preferably primarily made of a substance having a layered perovskite structure represented by the formula: A₂BO₄ (wherein A includes at least La, and B represents at least one element including at least Cu), and the n-type oxide thermoelectric conversion material is preferably primarily made of a substance having a layered perovskite structure represented by the formula: D₂EO₄ (wherein D includes at least one of Pr, Nd, Sm, and Gd, and E represents at least one element including at least Cu). In this case, it is possible to co-sinter the p-type oxide thermoelectric conversion material and the n-type oxide thermoelectric conversion material in air, thereby producing a thermoelectric conversion element having a high occupancy of the thermoelectric conversion materials.

Furthermore, when co-firing the p-type and n-type oxide thermoelectric conversion materials, the foregoing materials exhibit similar shrinking behavior during firing, thus preventing the occurrence of failures, such as cracking and delamination of the p-type and n-type oxide thermoelectric conversion materials, and further reducing the contact resistance between the p-type oxide thermoelectric conversion material and the n-type oxide thermoelectric conversion material.

The insulating material arranged between the p-type oxide thermoelectric conversion material and the n-type oxide thermoelectric conversion material preferably contains an oxide and a glass. In this case, the sinterability of the insulating material can be compatible with those of the p- and n-type oxide thermoelectric conversion materials. Thus, the p-type oxide thermoelectric conversion material, the n-type oxide thermoelectric conversion material, and the insulating material can be co-fired without using a special firing method or atmosphere.

Preferably, a material constituting the insulating film arranged on a surface to which the temperature difference is to be applied and constituting the insulating film arranged on a surface other than the above-referenced surface contains an oxide and a glass. It is thus possible to perform film formation easily and assuredly. Furthermore, the sinterability of the insulating film can be compatible with those of the p- and n-type oxide thermoelectric conversion materials. Thus, the p-type oxide thermoelectric conversion material, the n-type oxide thermoelectric conversion material, the insulating material arranged therebetween, and the insulating film arranged on the surface of the thermoelectric conversion materials can be co-fired without using a special firing method or atmosphere.

### BRIEF DESCRIPTION OF THE DRAWINGS

FIG. 1 shows the structure of a thermoelectric conversion module main body according to an example of the present invention.

FIG. 2 shows a thermoelectric conversion module according to an example of the present invention.

FIG. 3 shows a green compact (thermoelectric conversion module main body) produced in a step in a method for producing a thermoelectric conversion module according to an example of the present invention.

FIG. 4 shows a state in which a paste for an insulating film is applied onto heat transfer surfaces of a green compact (thermoelectric conversion module main body) produced in a step in a method for producing a thermoelectric conversion module according to an example of the present invention.

FIG. 5 shows a state in which the paste for an insulating film is also applied onto surfaces (side surfaces) other than the heat transfer surface of the green compact (thermoelectric conversion module main body) shown in FIG. 4.

FIG. 6 shows a state in which a Ag paste for a lead-out electrode is applied onto the green compact (thermoelectric conversion module main body) shown in FIG. 5.

FIG. 7 shows the structure of a thermoelectric conversion module according to a comparative example, the module being produced for comparison with the characteristics of a thermoelectric conversion module according to an embodiment of the present invention.

FIG. 8 shows a conventional thermoelectric conversion element (thermoelectric conversion module).

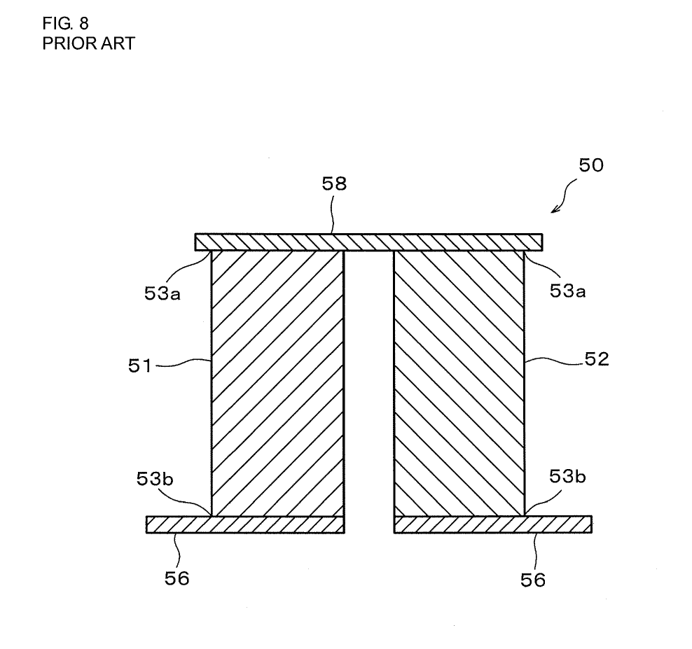

### REFERENCE NUMERALS

10 thermoelectric conversion element
10a, 10b adjacent thermoelectric conversion elements
11 p-type oxide thermoelectric conversion material
12 n-type oxide thermoelectric conversion material
13 insulating material
14a first lead-out electrode
14b second lead-out electrode
15 junction surface between p- and n-type oxide thermoelectric conversion materials
15a higher-temperature-side region of junction surface
15b lower-temperature-side region of junction surface
16a higher-temperature portion of thermoelectric conversion element
16b lower-temperature portion of thermoelectric conversion element
20 thermoelectric conversion module main body
20a upper surface
20b lower surface
20c, 20d, 20e, 20f side surface
21c, 21d, 21e, 21f insulating film arranged on side surface
30 thermoelectric conversion module
30a thermoelectric conversion module of comparative example
31a, 31b lead

### DETAILED DESCRIPTION OF THE INVENTION

Features of the present invention will be further described below by examples of the present invention.

### Examples

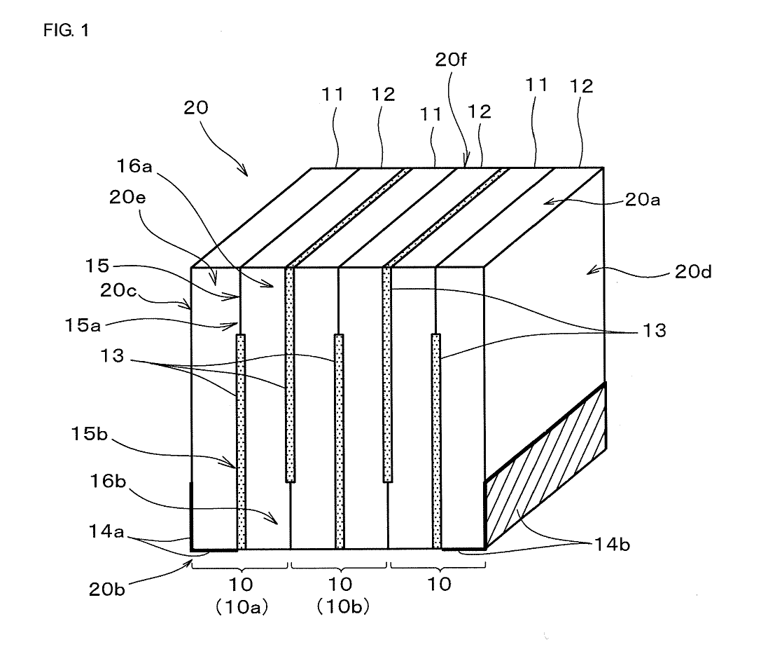

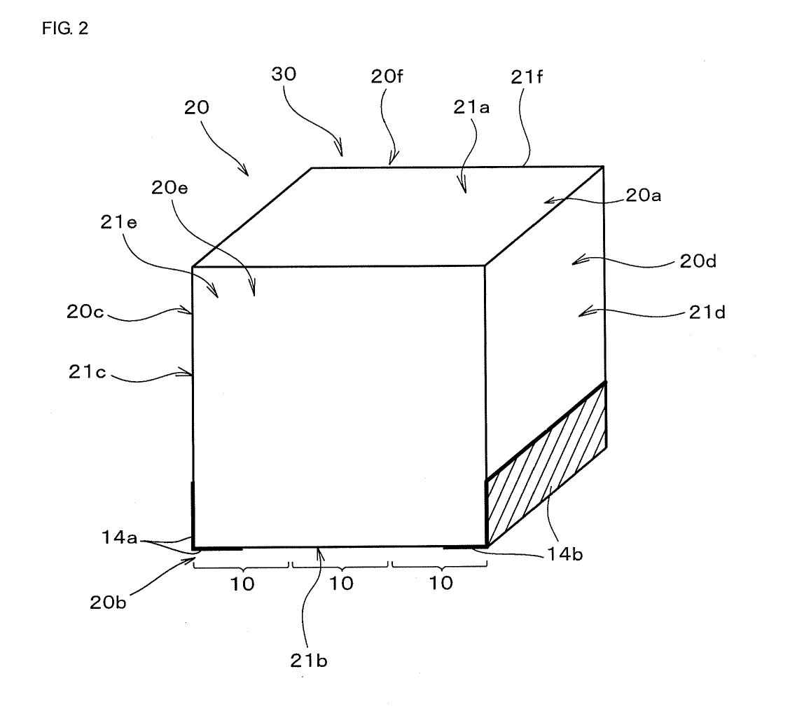

FIG. 1 shows the main body of a thermoelectric conversion module before surfaces, such as heat transfer surfaces, are covered with insulating films. FIG. 2 shows a thermoelectric conversion module according to an example of the present invention, surfaces of the thermoelectric conversion module being covered with insulating films.

A thermoelectric conversion module main body 20 (FIG. 1) included in a thermoelectric conversion module 30 (FIG. 2) according to this example includes a plurality of bonded thermoelectric conversion elements 10 each including a p-type oxide thermoelectric conversion material 11 (p-type oxide thermoelectric conversion material primarily made of an oxide) and an n-type oxide thermoelectric conversion material 12 (n-type oxide thermoelectric conversion material primarily made of an oxide); a first lead-out electrode 14a extending from a side surface 20c to a lower surface 20b; and a second lead-out electrode 14b extending from a side surface 20d to the lower surface 20b, the first lead-out electrode 14a and the second lead-out electrode 14b being located at lower portions of both ends (lower-temperature-side junction portions).

In each of the thermoelectric conversion elements 10 included in the thermoelectric conversion module main body 20, the p-type oxide thermoelectric conversion material 11 is directly bonded to the n-type oxide thermoelectric conversion material 12 without an electrode or the like provided therebetween in one region 15a (higher-temperature-side region) of a junction surface 15 between the p-type oxide thermoelectric conversion material 11 and the n-type oxide thermoelectric conversion material 12. In another region 15b (lower-temperature-side region) other than the one region 15a (higher-temperature-side region) of the junction surface 15, the p-type oxide thermoelectric conversion material 11 is bonded to the n-type oxide thermoelectric conversion material 12 with an insulating material 13 (composite insulating material) containing an oxide and a glass provided therebetween.

With respect to one thermoelectric conversion element 10 (10a) and another thermoelectric conversion element 10 (10b) adjacent to the thermoelectric conversion element 10 (10a), the n-type oxide thermoelectric conversion material 12 of the one thermoelectric conversion element 10 (10a) is directly bonded to the p-type oxide thermoelectric conversion material 11 of another thermoelectric conversion element 10 (10b) without an electrode or the like provided therebetween in a lower temperature portion 16b. In another portion 16a (higher temperature portion) other than the directly bonded lower temperature portion 16b, the n-type oxide thermoelectric conversion material 12 of the one thermoelectric conversion element 10 (10a) is bonded to the p-type oxide thermoelectric conversion material 11 of another thermoelectric conversion element 10 (10b) with the insulating material 13 containing an oxide and a glass provided therebetween.

The thermoelectric conversion module of this example has a structure in which the p- and n-type oxide thermoelectric conversion materials are directly connected to each other in the form of a meander so as to efficiently generate electric power.

FIG. 1 shows a structure that includes three thermoelectric conversion elements 10 each including a pair of the p-type oxide thermoelectric conversion material 11 and the n-type oxide thermoelectric conversion material 12. In fact, the thermoelectric conversion module of this example has 25 junctions (pn junctions) of the p-type oxide thermoelectric conversion material and the n-type oxide thermoelectric conversion material. However, in the present invention, the number of the thermoelectric conversion elements 10 included in the thermoelectric conversion module main body 20 is not particularly limited.

Insulating films 21a and 21b are arranged on a pair of surfaces, i.e., an upper surface 20a and the lower surface 20b, of the thermoelectric conversion module main body 20 to which a temperature difference is to be applied. Regions of the upper surface 20a and the lower surface 20b at which the p-type oxide thermoelectric conversion material 11 and the n-type oxide thermoelectric conversion material 12 are exposed are covered with the insulating films 21a and 21b.

In this example, a material which is primarily made of Al₂O₃ having a high thermal conductivity and being capable of efficiently conduct thermal energy from a heat source and which contains a glass is used as a material for the insulating films 21a and 21b arranged on the upper and lower surfaces, respectively, in order to ensure a sufficient temperature difference between the pair of surfaces to which a temperature difference is to be applied.

Thus, the thermoelectric conversion module 30 having the foregoing structure of this example can be arranged such that each of the upper surface 20a and the lower surface 20b, which are the pair of surfaces to which a temperature difference is applied, is in direct contact with the heat source even in the case of the heat source made of a conductive material, such as a metal. In this case, heat from the heat source can be more effectively used to achieve excellent thermoelectric conversion efficiency.

Furthermore, in the thermoelectric conversion module 30 of this example, four side surfaces 20c, 20d, 20e, and 20f of the thermoelectric conversion module main body 20 are also covered with insulating films 21c, 21d, 21e, and 21f, respectively.

Lower side regions of the pair of opposite side surfaces 20c and 20d are not covered with the insulating films 21c and 21d. Regions other than the lower side regions, i.e., upper side regions of the side surfaces 20c and 20d, are covered with the insulating films 21c and 21d, respectively.

The first lead-out electrode 14a and the second lead-out electrode 14b are arranged in the lower side regions of the pair of opposite side surfaces 20c and 20d that is not covered with the insulating films 21c and 21d.

A low-thermal-conductivity material, e.g., a glass or a substance containing a low-thermal-conductivity inorganic oxide and a glass, is preferably used as a material for the insulating films 21c, 21d, 21e, and 21f that cover the side surfaces 20c, 20d, 20e, and 20f from the viewpoint of ensuring a temperature difference between the upper surface 20a and the lower surface 20b, which are the pair of surfaces to which the temperature difference is to be applied. In this example, a material primarily made of Mg₂SiO₄ (forsterite), which is a material having a low thermal conductivity, and containing a glass is used.

Note that the material used for the insulating films 21c, 21d, 21e, and 21f that cover the side surfaces 20c, 20d, 20e, and 20f is the same as a material for the insulating material 13 arranged between the p-type oxide thermoelectric conversion material 11 and the n-type oxide thermoelectric conversion material 12, as described below.

The lead-out electrodes 14a and 14b are arranged on the lower sides of the side surfaces 20c and 20d. The lead-out electrodes 14a and 14b are preferably located closer to the lower ends from the viewpoint of ensuring a sufficient temperature difference between the pair of surfaces 20a and 20b. Furthermore, the areas of the lead-out electrodes 14a and 14b are preferably minimized.

In this example, the arrangement of the lead-out electrodes 14a and 14b extending from the lower sides of the side surfaces 20c and 20d to a region of the lower surface 20b results in improvement in the reliability of the bonding between the lead-out electrodes 14a and 14b and the thermoelectric conversion module main body 20 and improvement in the reliability of electrical connection between the outside and the thermoelectric conversion module main body 20, which is preferred.

Alternatively, the lead-out electrodes 14a and 14b may be arranged in only the lower end portion. That is, the lead-out electrodes 14a and 14b may not extend to the lower surface 20b.

In the thermoelectric conversion module 30, the insulating films 21c, 21d, 21e, and 21f are arranged on the side surfaces 20c, 20d, 20e, and 20f as described above. So, for example, when a thermoelectric conversion apparatus including the plural thermoelectric conversion modules 30 is produced, the plural thermoelectric conversion module main bodies 20 can be arranged so as to be in contact with each other with the insulating films 21c and 21d, thereby improving the packaging density of the thermoelectric conversion module.

In the thermoelectric conversion module 30 of this example, the p-type oxide thermoelectric conversion material is primarily made of a substance having a layered perovskite structure represented by the formula: A₂BO₄.

In the formula A₂BO₄ of the p-type oxide thermoelectric conversion material 11, A preferably includes La (lanthanum). Furthermore, A is preferably substituted by Sr in the form of A₂₋ₓSrₓ, provided that 0≦x<0.2. The selection of La as A enables the production of the p-type thermoelectric conversion material. In addition, the substitution of Sr in the range of 0≦x<0.2 results in a reduction in the resistance of the material. At a Sr content of 0.2 or more, although the effect of reducing resistance is provided, a Seebeck coefficient is low, generating only a low electromotive force, which is not preferred.

B represents one or a plurality of elements including at least Cu.

The n-type oxide thermoelectric conversion material is primarily made of a substance having a layered perovskite structure represented by the formula: D₂EO₄.

In the formula D₂EO₄ of the n-type oxide thermoelectric conversion material 12, D preferably includes at least one of Pr (praseodymium), Nd (neodymium), Sm (samarium), and Gd (gadolinium).

Furthermore, D is preferably substituted by Ce in the form of D_{2-y}Ce_{y}, provided that 0≦y<0.2. The selection of at least one of Pr, Nd, Sm, and Gd as D permits the production of the n-type thermoelectric conversion material. In addition, the substitution of Ce in the range of 0≦y<0.2 results in a reduction in the resistance of the material. At a Ce content of 0.2 or more, although the effect of reducing resistance is provided, a Seebeck coefficient is low, generating only a low electromotive force, which is not preferred.

E represents one or a plurality of elements including at least Cu.

A mixture of an oxide and a glass is used as the insulating material arranged between the p-type oxide thermoelectric conversion material and the n-type oxide thermoelectric conversion material. Materials for the mixture and its composition are appropriately selected in view of conditions required for co-firing with the p-type oxide thermoelectric conversion material and the n-type oxide thermoelectric conversion material.

In this example, a material that is primarily made of Mg₂SiO₄ (forsterite), which is a material having a low thermal conductivity, and that contains a glass is used as the insulating material in order to inhibit the dissipation of heat to adjacent thermoelectric conversion materials and sufficiently ensure a temperature difference between two surfaces to which the temperature difference is to be applied. Alternatively, BaTiO₃ may be used.

With respect to a glass contained in the insulating material arranged between the p-type oxide thermoelectric conversion material and the n-type oxide thermoelectric conversion material, a composition having sinterability compatible with those of the p-type material and the n-type material is appropriately selected. In this example, a borosilicate glass is used.

The glass content of the insulating material is not particularly limited as long as the insulating material can be co-fired with the oxide thermoelectric conversion materials. A higher glass content can cause diffusion of the constituent elements of the glass into the thermoelectric conversion materials, thereby reducing the output characteristics. Thus, the glass content of the composite insulating material is preferably in the range of 5% by weight to 25% by weight.

In this example, the lead-out electrodes 14a and 14b are arranged on the lower-temperature side, the first lead-out electrode 14a extending from the side surface 20c to the lower surface 20b, and the second lead-out electrode 14b extending from the side surface 20d to the lower surface 20b. The arrangement of the first and second lead-out electrodes 14a and 14b is not particularly limited to this arrangement. The electrodes may be arranged on the higher-temperature side. However, if problems of oxidation of the electrodes and migration arise when the electrodes are arranged on the higher-temperature side, the electrodes are preferably arranged on the lower-temperature side.

### [Method for Producing Thermoelectric Conversion Module]

A method for producing the thermoelectric conversion module 20 will be described below.

La₂O₃, SrCO₃, and CuO were prepared as starting materials for a p-type oxide thermoelectric conversion material. Furthermore, Nd₂O₃, CeO₂, and CuO were prepared as starting materials for an n-type oxide thermoelectric conversion material.

These starting materials were weighed so as to satisfy compositions shown in Table 1.

TABLE 1

| | p-Type oxide | n-Type oxide |
|---|---|---|
| | thermoelectric | thermoelectric |
| | conversion material | conversion material |
| Example | (La_{1.97}Sr_{0.03})CuO₄ | (Nd_{1.97}Ce_{0.03})CuO₄ |

Alternatively, Pr₆O₁₁, CeO₂, and CuO may be used as starting materials for the n-type oxide thermoelectric conversion material to provide a thermoelectric conversion module including the n-type oxide thermoelectric conversion material having a composition expressed as (Pr_{1.95}Ce_{0.05})CuO₄.

(2) Deionized water was added as a solvent to these powders. The resulting mixtures were mixed for 16 hours by ball milling to form slurries. The slurries were dried and then calcined at 900° C. in air.

(3) The calcined powders were pulverized for 40 hours by ball milling. Deionized water, a binder, and so forth were added to the resulting powders to form slurries. The resulting slurries were formed into sheets by a doctor blade method, thereby producing 50-μm-thick green sheets for the p- and n-type oxide thermoelectric conversion materials.

(4) With respect to a paste for an insulating material provided between the p-type oxide thermoelectric conversion material and the n-type oxide thermoelectric conversion material, a Mg₂SiO₄ powder, a glass powder, varnish, and a solvent were mixed. The mixture was kneaded with a roll mill to produce an insulating material paste (Mg₂SiO₄ paste) having a low thermal conductivity, for the purpose of increasing a temperature difference between elements. As the glass powder, a borosilicate glass was used in view of compatibility with sinterability of the p-type oxide thermoelectric conversion material and the n-type oxide thermoelectric conversion material.

In this example, the insulating material paste (Mg₂SiO₄ paste) is also used as a paste for the insulating films 21c and 21d arranged on the pair of opposite side surfaces 20c and 20d.

(5) With respect to a paste arranged to cover a region of a surface (heat transfer surface) at which the p-type oxide thermoelectric conversion material and the n-type oxide thermoelectric conversion material are exposed and to which a temperature difference is to be applied, Al₂O₃, which is a material having a high thermal conductivity, was used as a main component in order to reduce heat transfer loss to a thermoelectric conversion module. A glass powder, varnish, and a solvent were added thereto. The mixture was kneaded with a roll mill to produce a paste (Al₂O₃ paste) arranged to form the insulating films.

The glass powder is selected in view of compatibility with sinterability of the p-type oxide thermoelectric conversion material and the n-type oxide thermoelectric conversion material. In this example, a borosilicate glass was used which has the same composition as that of the glass used in the insulating material paste arranged between the p-type oxide thermoelectric conversion material and the n-type oxide thermoelectric conversion material.

(6) The resulting insulating material paste (Mg₂SiO₄ paste) was applied by printing on the resulting green sheets for the p- and n-type thermoelectric conversion materials to form 10-μm-thick films.

(7) Then (a) four p-type oxide thermoelectric conversion material green sheets on which the insulating material paste had not been applied by printing, (b) one p-type oxide thermoelectric conversion material green sheet on which the insulating material paste was applied by printing to form the 10-μm-thick film, (c) four n-type oxide thermoelectric conversion material green sheets on which the insulating material paste had not been applied by printing, and (d) one n-type oxide thermoelectric conversion material green sheet on which the insulating material paste was applied by printing to form the 10-μm-thick film were stacked, in that order, to form a stack that defines one thermoelectric conversion element. Twenty-five stacks were alternately stacked to form a laminate.

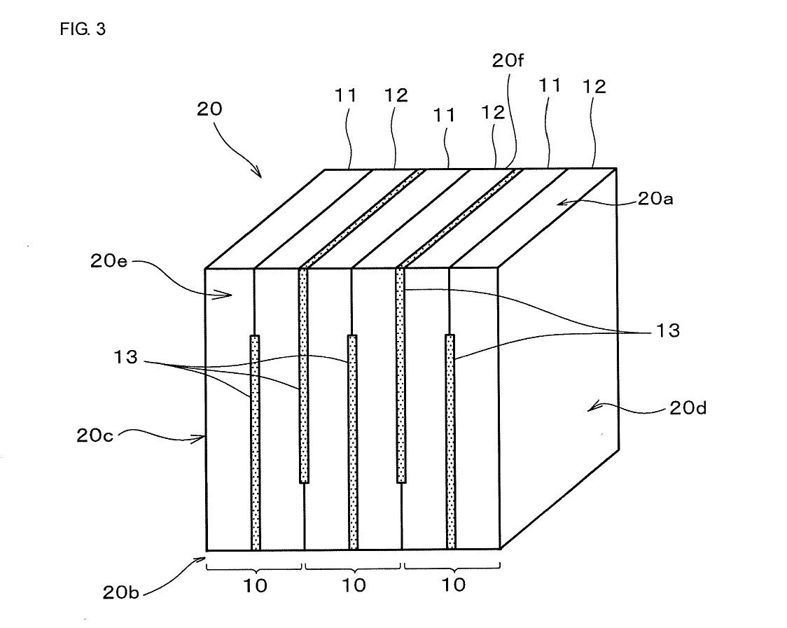

(8) The resulting laminate was press-bonded by isostatic pressing at 200 MPa and cut into pieces each having a predetermined size with a dicing saw, thereby producing green compacts, having a structure as shown in FIG. 3, to be formed into the thermoelectric conversion module main body 20 after firing.

In FIG. 3, for easy understanding, components are designated using the same reference numerals that denote equivalent components of the thermoelectric conversion module main body 20 after firing (FIG. 1).

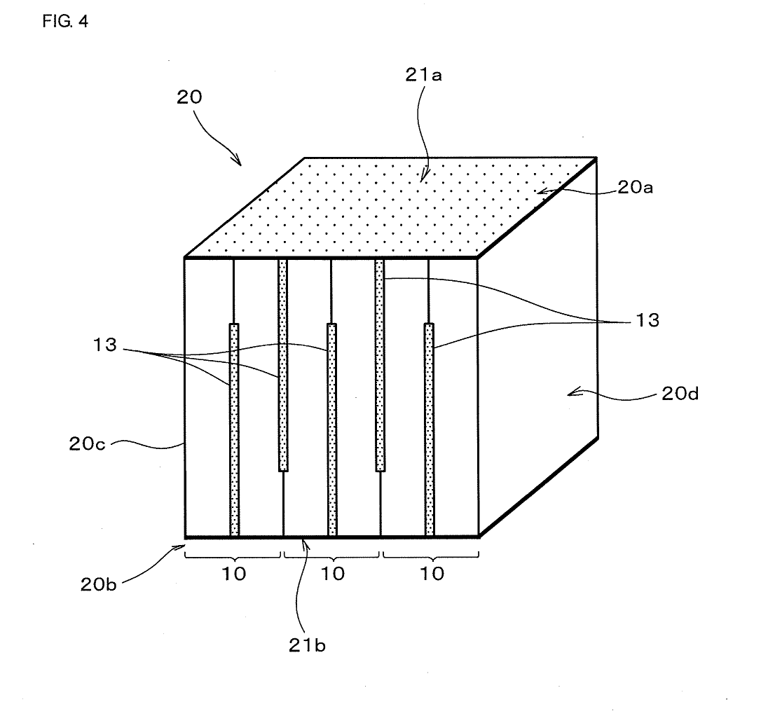

(9) As shown in FIG. 4, the paste for the insulating films (paste to be formed into the insulating films 21a and 21b after firing) was applied onto the upper surface 20a and the lower surface 20b, which are the pair of surfaces to which a temperature difference is to be applied, of the green compact, the paste containing Al₂O₃ powder, which is a material having a high thermal conductivity, and a glass component.

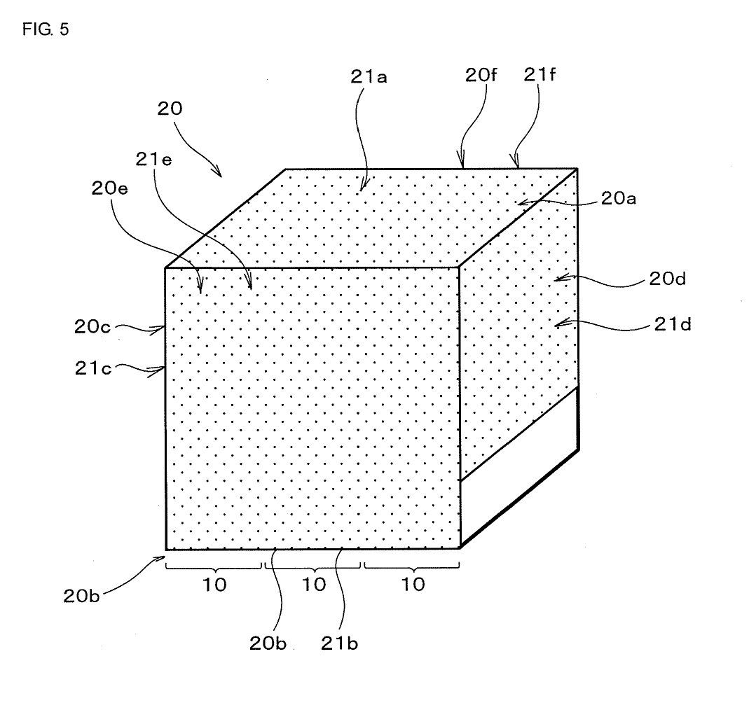

(10) As shown in FIG. 5, the paste (Mg₂SiO₄ paste) (paste to be formed into the insulating films 21c, 21d, 21e, and 21f after firing) primarily containing a material having a low thermal conductivity was applied onto four side surfaces 20c, 20d, 20e, and 20f of each of the green compacts.

In this case, the paste was not applied on the lower side regions of the side surfaces 20c and 20d where the lead-out electrodes 14a and 14b are to be arranged.

Alternatively, the insulating films 21c and 21d may be formed as follows: in the foregoing step of forming the laminate to be formed into one thermoelectric conversion element, p-type oxide thermoelectric conversion material green sheets on which the insulating material paste to be formed into the insulating film 21c or 21d after firing is applied by printing in a predetermined pattern are stacked so as to serve as outermost layers of the laminate.

(11) The resulting compacts were degreased at 480° C. and then fired in air at 900° C. to 1050° C. to produce sintered compacts, which were thermoelectric conversion modules before the formation of lead-out electrodes.

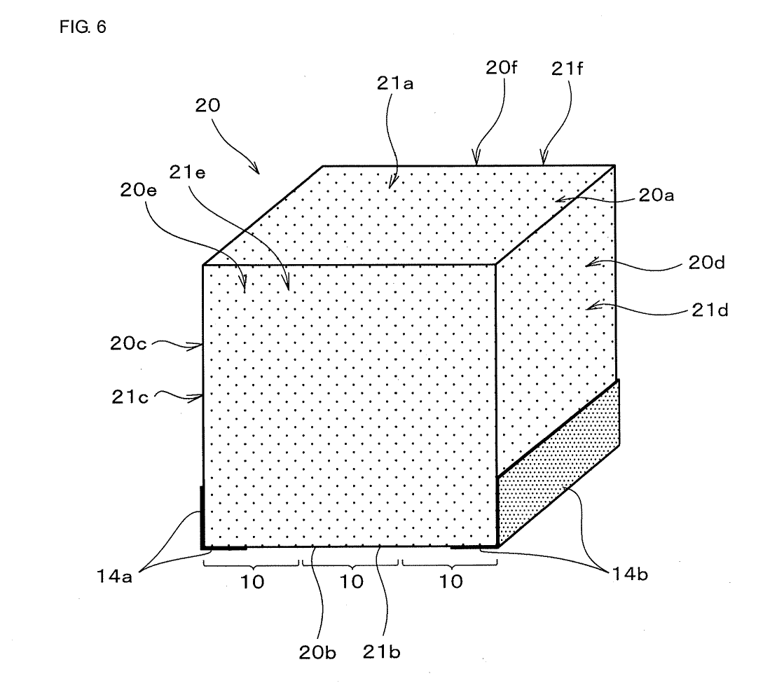

(12) After polishing each sintered compact, as shown in FIG. 6, a Ag paste (paste to be formed into the lead-out electrodes 14a and 14b (Ag electrodes) after firing) was applied by screen printing from lower end portions of both side surfaces 20c and 20d to the lower surface 20b and baked at about 700° C. Thereby, the thermoelectric conversion module 30 (FIG. 2) having a structure as shown in FIGS. 1 and 2 was produced.

As a material constituting the lead-out electrodes 14a and 14b, a material having a low contact resistance to the thermoelectric conversion element may be used. Various known electrode materials may be used.

### [Characteristic Evaluation 1]

To evaluate characteristics, a thermoelectric conversion module unit (unit of the example) including two thermoelectric conversion modules connected in series was produced, each thermoelectric conversion module having the structure described in the foregoing example and having 25 junctions (pn junctions) between the p-type oxide thermoelectric conversion materials and the n-type oxide thermoelectric conversion materials.

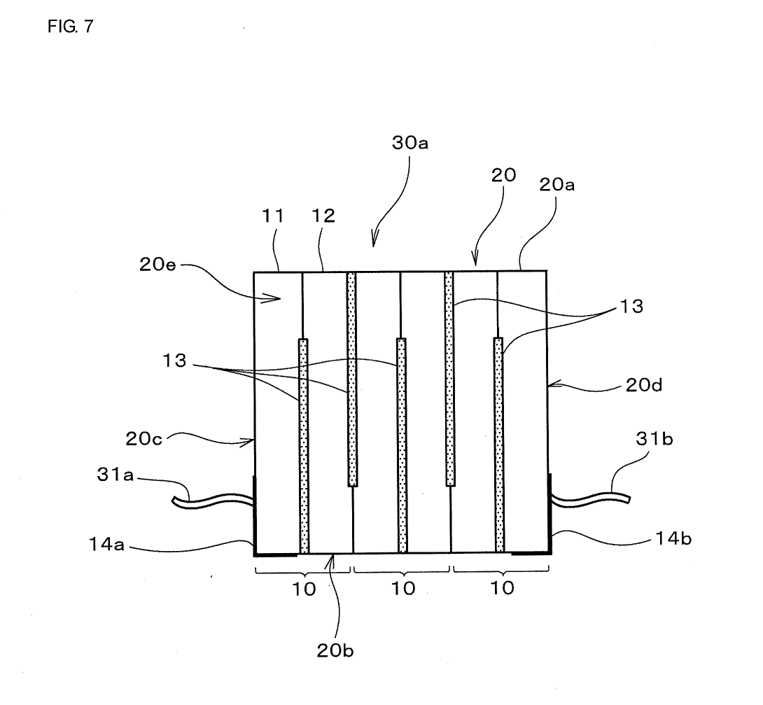

For comparison, a comparative thermoelectric conversion module 30a having a structure as shown in FIG. 7 was produced. The thermoelectric conversion module 30a includes 25 junctions (pn junctions) between the p-type oxide thermoelectric conversion materials and the n-type oxide thermoelectric conversion materials. The thermoelectric conversion module 30a has the same structure as the thermoelectric conversion module 30 of the example shown in FIG. 2, except that

the lead-out electrodes 14a and 14b were arranged on only the lower end portions of the side surfaces 20c and 20d and were not arranged on the lower surface 20b;

the upper and lower surfaces, to which a temperature difference is to be applied, and other surfaces were not covered with an insulating film; and

the lead-out electrodes 14a and 14b arranged on the lower end portions of the side surfaces were connected to leads 31a and 31b each having a diameter of 0.5 mm with solder.

A thermoelectric conversion module unit (unit of a comparative example) including two comparative thermoelectric conversion modules 30a connected in series was produced.

With respect to the unit of the example including the thermoelectric conversion modules of the example described above and the unit of the comparative example including the comparative thermoelectric conversion modules, output and dimensions in plan were measured to determine output per unit area. To determine the output, the temperatures were adjusted such that the lower surface located on the lower-temperature side had a temperature of 20° C. and such that the upper surface located on the higher-temperature side had a temperature of 400° C. The voltage and the current were measured by changing a load connected to each thermoelectric conversion module with an electronic load device to calculate the output. Table 2 shows the results.

TABLE 2

| | | Unit of comparative |
|---|---|---|
| | Unit of example | example |
| Output (W) | 0.0440 | 0.0424 |
| Area dimension | 0.9 × 1.6 | 2.0 × 0.8 |
| (cm × cm) | | |
| Output per unit | 0.0306 | 0.0265 |
| area (W/cm²) | | |

As shown in Table 2, for the thermoelectric conversion module unit of the example (unit of the example), because the side surfaces are covered with the insulating films, the temperature difference between the upper surface and the lower surface can be larger than that of the thermoelectric conversion module unit of the comparative example, thereby increasing the output.

With respect to the dimensions in plan, for the thermoelectric conversion module unit of the comparative example (unit of the comparative example), the dimensions in plan (area in plan) were increased because the surfaces were not covered with an insulating film and the thermoelectric conversion modules must be separated from each other so as not to come into contact with each other. In the thermoelectric conversion module unit of the comparative thermoelectric conversion module, the interval between the two thermoelectric conversion modules varies depending on various conditions. So, the data of the dimensions in plan shown in Table 2 is merely an example. It is clear that for the thermoelectric conversion module unit of the example, because the surfaces are covered with the insulating films, the pair of thermoelectric conversion elements can be arranged so as to be in close contact with each other, thereby reducing the dimensions in plan as compared to the case of the comparative example.

Furthermore, for the thermoelectric conversion module unit of the example, the temperature difference between the heat transfer surfaces can be increased as compared to the thermoelectric conversion module unit of the comparative example. Moreover, the high output and the small area in plan result in high output per unit area.

[Characteristic Evaluation 2]

A thermoelectric conversion module (sample of the example for characteristic evaluation 2) the same as the thermoelectric conversion module 30 (see FIGS. 1 and 2) of the foregoing example was prepared as a thermoelectric conversion module according to the example of the present invention.

Furthermore, a thermoelectric conversion module (sample of the comparative example for characteristic evaluation 2) having the same structure as the sample of the example for characteristic evaluation 2 was prepared, except that the upper and lower surfaces and four side surfaces were not covered with an insulating film.

In characteristic evaluation 2, each of the sample of the example and the sample of the comparative example was interposed between a stainless heater and a water-cooled copper heat sink. The temperature of the stainless heater was set to 400° C. The temperature of the water-cooled copper heat sink was set to 20° C. The output was measured with an electronic load device.

The results demonstrated that the thermoelectric conversion module of the example for characteristic evaluation 2 had an output of 0.025 W and an output per unit area of 0.035 W/cm². For the thermoelectric conversion module of the comparative example, however, the contact of the module with the stainless heater and the water-cooled copper heat sink caused the p-type oxide thermoelectric conversion material and the n-type oxide thermoelectric conversion material to be short-circuited. Thus, the voltage was lower than the measuring limit, failing to generate electric power.

Even if the thermoelectric conversion module of the example for characteristic evaluation 2 has a structure in which an insulating film is not arranged on the side surfaces other than the heat transfer surfaces, the module has substantially the same characteristics as those measured in characteristic evaluation 2 described above.

In the foregoing example, the case where the insulating films are arranged on all surfaces of the thermoelectric conversion module, i.e., the case where the insulating films are arranged on the upper and lower surfaces and the side surfaces, has been described above. In the thermoelectric conversion module of the present invention, if at least one surface of the pair of surfaces to which a temperature difference is applied is covered with the insulating film, the basic effect of the present invention can be provided. That is, the module is arranged so as to be in contact with a heat source made of an electrically conductive material, such as a metal having excellent thermal conductivity, so that heat from the heat source is effectively used, thereby providing the effect of improving the thermoelectric conversion efficiency.

Thus, the module may have a structure in which the insulating film is arranged on one surface of the pair of surfaces to which a temperature difference is to be applied and in which an insulating film is not arranged on the other surface.

Furthermore, the module may have a structure in which the insulating film is not arranged on one or all of the side surfaces. This structure is also in the range of the present invention.

In the foregoing example, the case has been described in which the pair of surfaces to which a temperature difference is applied is defined as the upper surface and the lower surface. Alternatively, the pair of surfaces to which a temperature difference is applied may not be necessarily defined as the upper surface and the lower surface, depending on the shape of each thermoelectric conversion material, the stacking structure, the shape of the thermoelectric conversion module main body, and so forth.

In the foregoing example, the oxides and carbonate are used as raw materials for the thermoelectric conversion materials and the insulating materials. Alternatively, any other material, e.g., hydroxide or alkoxide, may be used as long as it is fired to form a metal oxide. The form of the raw material is not particularly limited.

In the present invention, the particle size of the starting material powders is not particularly limited. However, the particle size is preferably selected in view of uniform mixing. Furthermore, the time of pulverizing and mixing by ball milling is not particularly limited. However, the time is preferably determined in view of uniform mixing.

In the foregoing example, the raw materials of the p- and n-type oxide thermoelectric conversion materials are weighed so as to satisfy the compositions as shown in Table 1 and so forth. SrCO₃, CeO₂, and other additives are appropriately selected, depending on necessary thermoelectric properties, power generation characteristics, and conditions required for co-sintering. Furthermore, another element, a glass, or the like may be added if it is needed for co-sintering.

In the foregoing example, while calcination was performed at 900° C., the firing method and conditions are not particularly limited. In the foregoing example, however, the reaction does not proceed at a low firing temperature, failing to provide a target copper oxide. So, the calcination temperature is preferably set to 800° C. or higher.

In the foregoing example, while the pulverization time by ball milling after the calcination was set to 40 hours, the pulverization time by ball milling after the calcination is not particularly limited as long as the powders such that the p- and n-type oxide thermoelectric conversion materials can be co-sintered are obtained.

In the foregoing example, Mg₂SiO₄ having a low thermal conductivity and a glass were used as a material for the insulating films arranged on the side surfaces and the insulating material arranged between the p-type oxide thermoelectric conversion material and the n-type oxide thermoelectric conversion material. Al₂O₃ having a high thermal conductivity and a glass were used as a material for the insulating films arranged on the surfaces to which a temperature difference is applied. However, the oxides and the glasses are appropriately selected, depending on conditions required for co-sintering of the p-type oxide thermoelectric conversion material, the n-type oxide thermoelectric conversion material, the insulating material, and the insulating films that cover the surfaces. Constituent elements of the glasses are not particularly limited. Furthermore, the oxide content and the glass content are not particularly limited as long as the insulating material and the insulating films can be co-sintered with the thermoelectric conversion materials. A higher glass content is liable to cause diffusion of the constituent elements of the glasses into the thermoelectric conversion materials, thereby reducing the output characteristics. Thus, the glass content is preferably in the range of 5% by weight to 25% by weight.

The material for the insulating films (e.g., a paste for the insulating films) preferably contains a glass component from the viewpoint of achieving good mechanical strength of the insulating films.

Furthermore, the softening point of the glass used in each of the insulating material and the insulating films is not particularly limited. In the example, the firing temperature of the compact is in the range of 900° C. to 1050° C. A lower softening point of the glass results in diffusion of the constituent elements of the glass into the thermoelectric conversion materials, thereby reducing the output characteristics. Thus, the glass preferably has a softening point of 550° C. to 750° C.

The material for the insulating films arranged on the surfaces (heat transfer surfaces) preferably has a high thermal conductivity as compared to those of the insulating material arranged between the p-type oxide thermoelectric conversion material and the n-type oxide thermoelectric conversion material and the material for the insulating films arranged on the side surfaces. The reason for this is because thermal energy is efficiently transferred from a heat source, as described above.

In the foregoing example, while the number of pn junctions was set to 25, preferably, the number of pn junctions is appropriately determined in view of a target electromotive force, current, load resistance used, and so forth.

In the foregoing example, while the laminate was press-bonded by isostatic pressing, any press bonding method may be employed.

In the foregoing example, while the firing was performed at 900° C. to 1050° C. in air, any firing method, e.g., hot pressing, SPS sintering, or HIP sintering, may be employed. Furthermore, the firing temperature and the atmosphere are not specified. However, sintering does not proceed at a low temperature. So, usually, the firing is preferably performed at a temperature such that a relative density of 90% or more is achieved and such that co-sintering can be performed.

With respect to a method for forming the insulating film on the heat transfer surface, a preferred method includes the steps of applying the insulating material paste onto the heat transfer surfaces and performing co-firing, as described in the example. Alternatively, a method in which a metal film is formed on a heat transfer surface and then oxidized into an insulating film, a method using a thin-film formation process, such as sputtering, and so forth may be employed. A method for forming the insulating film is not particularly limited.

Regarding a method for forming an insulating film on a heat transfer surface without performing co-sintering, the following method may be exemplified.

As with the step (7) in Section [Method for Producing Thermoelectric Conversion Module] of the foregoing example, predetermined numbers of (a) p-type oxide thermoelectric conversion material green sheets on which the insulating material paste is not applied by printing, (b) p-type oxide thermoelectric conversion material green sheets on which the insulating material paste is applied by printing, (c) n-type oxide thermoelectric conversion material green sheets on which the insulating material paste is not applied by printing, and (d) n-type oxide thermoelectric conversion material green sheets on which the insulating material paste is applied by printing are stacked in that order. The resulting stack is press-bonded to form a laminate. The laminate is fired under predetermined firing conditions, thereby providing a sintered monolithic thermoelectric conversion element (thermoelectric conversion module main body) having an integrated p-type oxide thermoelectric conversion material/insulating material/n-type oxide thermoelectric conversion material structure.

A paste for an insulating film, the paste containing an alumina powder and a glass powder (e.g., borosilicate glass) that melts at a temperature higher than the temperature of a heat source, is applied onto the heat transfer surfaces (a pair of surfaces to which a temperature difference is to be applied) of the sintered thermoelectric conversion module main body.

Heat treatment is performed at a predetermined temperature (for example, 800° C.), thereby forming insulating films on the heat transfer surfaces of the thermoelectric conversion module main body.

In this way, it is possible to form the insulating films on the heat transfer surfaces of the sintered thermoelectric conversion module main body without using co-firing.

Furthermore, it is possible to form insulating films on side surfaces of the sintered thermoelectric conversion module main body in a similar manner.

In the case of employing the method without performing co-firing, various materials may be used as materials for the insulating films arranged on the heat transfer surfaces and the side surfaces as long as the materials withstand the temperature of the heat source, thus improving flexibility in the choice of materials.

Specifically, various organic materials, such as thermosetting resins, e.g., epoxy resins, may be used as long as they withstand the temperature of the heat source.

The present invention is not limited to the foregoing example. With respect to the compositions and raw materials of the p-type oxide thermoelectric conversion material and the n-type oxide thermoelectric conversion material, the compositions and raw materials of the insulating material of the p-type oxide thermoelectric conversion material and the n-type oxide thermoelectric conversion material, types of raw materials defining the insulating films arranged on the surfaces to which a temperature difference is to be applied, types of raw materials defining the insulating films arranged on other surfaces, the glass contents thereof, specific structures of the thermoelectric conversion module, and specific production conditions (e.g., the dimensions, the firing conditions, the number of thermoelectric conversion elements defining the thermoelectric conversion module), variations and modifications can be made within the scope of the invention.

According to the present invention, as described above, it is possible to provide a thermoelectric conversion module which has a high occupancy of thermoelectric conversion materials, which is capable of being directly attached to a heat source made of a conductive material, such as a metal, having excellent heat transfer properties, which has excellent thermoelectric conversion efficiency, and to which a temperature difference is easily applied.

Thus, the present invention is widely applied in various technical fields when heat is directly converted into electricity.

1. A thermoelectric conversion module comprising:
a module body comprising a p-type oxide thermoelectric conversion material and an n-type oxide thermoelectric conversion material, wherein the p-type oxide thermoelectric conversion material is directly bonded to the n-type oxide thermoelectric conversion material in a first region of a junction surface between the p-type oxide thermoelectric conversion material and the n-type oxide thermoelectric conversion material, and the p-type oxide thermoelectric conversion material is bonded to the n-type oxide thermoelectric conversion material with an insulating material provided therebetween in a second region of the junction surface to form a pn junction;
a pair of lead-out electrodes arranged to output electric power generated by a temperature difference applied to the pn junction, and
an insulating film covering a region of at least one surface of a pair of surfaces at which the p-type oxide thermoelectric conversion material and the n-type oxide thermoelectric conversion material are exposed and to which the temperature difference is applied.

2. The thermoelectric conversion module according to claim 1, wherein the insulating film covers a region of each of the pair of surfaces at which the p-type oxide thermoelectric conversion material and the n-type oxide thermoelectric conversion material are exposed and to which the temperature difference is applied.

3. The thermoelectric conversion module according to claim 1, wherein a second insulating film covers a region of a surface other than the surfaces at which the p-type oxide thermoelectric conversion material and the n-type oxide thermoelectric conversion material are exposed and to which the temperature difference is applied.

4. The thermoelectric conversion module according to claim 1, wherein the insulating film is different from the second insulating film.

5. The thermoelectric conversion module according to claim 1, wherein the thermoelectric conversion module is in the form of a rectangular parallelepiped, and wherein each of the pair of lead-out electrodes extends from a corresponding one of a pair of side surfaces to the bottom surface, the pair of side surfaces being adjacent to the bottom surface, and the bottom surface being configured to face a component on which the thermoelectric conversion module is mounted.

6. The thermoelectric conversion module according to claim 1, wherein the p-type oxide thermoelectric conversion material, the n-type oxide thermoelectric conversion material, and the insulating material are co-sintered.

7. The thermoelectric conversion module according to claim 1, wherein the insulating film is co-sintered with the p-type oxide thermoelectric conversion material, the n-type oxide thermoelectric conversion material, and the insulating material.

8. The thermoelectric conversion module according to claim 1, wherein the p-type oxide thermoelectric conversion material is primarily composed of a substance having a layered perovskite structure represented by the formula A₂BO₄ wherein A includes at least La, and B represents at least one element including at least Cu.

9. The thermoelectric conversion module according to claim 8, wherein the n-type oxide thermoelectric conversion material is primarily made of a substance having a layered perovskite structure represented by the formula D₂EO₄
wherein D includes at least one of Pr, Nd, Sm, and Gd, and E represents at least one element including at least Cu.

10. The thermoelectric conversion module according to claim 1, the n-type oxide thermoelectric conversion material is primarily made of a substance having a layered perovskite structure represented by the formula D₂EO₄
wherein D includes at least one of Pr, Nd, Sm, and Gd, and E represents at least one element including at least Cu.

11. The thermoelectric conversion module according to claim 1, wherein the insulating material arranged between the p-type oxide thermoelectric conversion material and the n-type oxide thermoelectric conversion material contains an oxide and a glass.

12. The thermoelectric conversion module according to claim 1, wherein the insulating film contains an oxide and a glass.
